(19) United States
(12) Patent Application Publication
(10) Pub. No.: US 2012/0032338 A1
(43) Pub. Date: Feb. 9, 2012

(54) SEMICONDUCTOR DEVICE AND METHOD FOR FABRICATING THE SAME

(75) Inventor: Kenji Komori, Miyazaki (JP)

(73) Assignee: OKI SEMICONDUCTOR CO., LTD., TOKYO (JP)

(21) Appl. No.: 13/193,645

(22) Filed: Jul. 29, 2011

(30) Foreign Application Priority Data
Aug. 9, 2010 (JP) 2010-178744

(51) Int. Cl. H01L 23/48; H01L 21/28

(52) U.S. Cl. 257/773; 438/652; 257/E23.01; 257/E21.158

(57) ABSTRACT

Disclosed is a semiconductor device which includes a base substrate; a lower electrode formed on a main surface of the base substrate; and an insulating film formed over the lower electrode and the main surface of the base substrate. The insulating film has a contact hole defined by a wall extending upwardly from the top surface of the lower electrode. The insulating film has a film density distribution in which a film density decreases with increasing distance from the main surface of the base substrate in the thickness direction. A width of the contact hole increases as the film density decreases.

### BACKGROUND OF THE INVENTION

1. Field of the Invention

The present invention relates to semiconductor techniques for forming an insulating film.

2. Description of the Related Art

Passivation films are widely used to protect semiconductor integrated circuits and/or interconnects of semiconductor structures from mechanical damage and external contaminants such as water and moisture. A passivation film can have contact holes which are used to electrically connect lower electrodes (e.g., electrode pads) to terminal electrodes for external connection. In each contact hole of the passivation film, a barrier-metal film can be formed over the lower electrode. Poor step coverage of the barrier-metal film over the contact hole possibly causes nonuniformity of the thickness of the barrier-metal film on the bottom of the contact hole. This causes diffusion of external contaminants and/or constituent atoms of the terminal electrode into a lower layer, leading to poor electrical characteristics of semiconductor devices.

FIGS. 1A and 1B are cross-sectional views of semiconductor structures, each including an exemplary passivation film 101 that has a contact hole 101h above a lower electrode 102 formed on a substrate 100. The passivation film 101 can be formed by depositing a nitride film over the lower electrode 102 by, for example, plasma CVD (plasma chemical vapor deposition), and then patterning the nitride flirt by dry-etching to form the contact hole 101h. FIG. 1A illustrates an ideal wall of the contact hole 101h that is substantially perpendicular to the top surface of the lower electrode 102. In contrast, FIG. 1B illustrates a notch or void 101n formed at the bottom of the contact hole 101h by over-etching of the nitride film.

FIG. 2A is a cross-sectional view illustrating the shape of the barrier-metal film 103 covering the contact hole 101h of FIG. 1A, and FIG. 2B is a cross-sectional view illustrating the shape of the barrier-metal film 103 covering the contact hole 101h of FIG. 1B. These barrier-metal films 103 can be deposited by, for example, sputtering of high melting point refractory metals such as titanium (Ti) and tungsten (W). As illustrated in FIG. 2A, a portion of the barrier-metal film 103 at the bottom of the contact hole 101h is likely to be thin compared with a portion of the barrier-metal film 103 on the passivation film 103. As illustrated in FIG. 2B, the notch or void 101n leads to a discontinuous deposition of the barrier-metal film 103. Both the structures of FIGS. 2A and 2B cause poor step coverage of the barrier-metal film 103 over the contact hole 101h, leading to poor electrical characteristics of semiconductor devices.

Contact holes or through-holes for electrical connections of lower interconnect layer to upper interconnect layers are also etched in interlayer dielectric films of semiconductor devices, leading to similar problems as in the case of the contact holes of the passivation films.

Japanese Patent Application Publication No. H05(1993)-102106 discloses a technique for forming a tapered contact hole, which improves step coverage over the contact hole etched in a passivation film and/or interlayer dielectric film. In this technique, a photoresist layer is coated on an insulating film, and patterned to form an opening in the photoresist layer. The patterned photoresist layer is then deformed by exposure to ultraviolet light and heat treatment, thereby to form a gently sloping wall facing the opening. The dry-etching of the insulating film is then carried out using the patterned photoresist layer as an etch mask. In this dry-etching process, the gently sipping wall of the patterned photoresist layer is simultaneously etched back. Thus, a tapered contact hole in the insulating film is formed.

However, the first problem with this technique is that the number of process steps is increased to include the step of deforming the patterned photoresist layer by exposing to ultraviolet light and the heat treatment, thereby increasing manufacturing cost. The second problem is that it is difficult to deform, with a desired high accuracy, the patterned photoresist layer, thus causing difficulty for controlling, with a high accuracy, the tapered shape of the contact hole of the insulating film.

Japanese Patent Application Publication No. 2005-57101 discloses a multiple-exposure photolithography technique for forming a contact hole or concave portion with a tapered wall in an insulating film. This multiple-exposure photolithography technique includes a number of exposure steps that uses a number of exposure masks with their respective openings of different sizes, to form the contact hole with the tapered side wall.

The problem with the multiple-exposure photolithography technique is that manufacturing cost is greatly increased by multiple exposure steps using a number of exposure masks. Conversely, it is difficult to control the tapered shape of the contact hole when the exposure step is performed once or a small number of times.

In view of the foregoing, it is an object of the present invention to provide a semiconductor device and a method of fabricating the semiconductor device which enables accurate control of the shape of a contact hole of an insulating film with low fabrication cost.

### SUMMARY OF THE INVENTION

According to an aspect of the present invention, there is provided a semiconductor device which includes: a base substrate; a lower electrode formed on a main surface of the base substrate; and an insulating film formed over the lower electrode and the main surface of the base substrate and having a contact hole defined by a wall extending upwardly from a top surface of the lower electrode. The insulating film has a film density distribution in which a film density decreases with increasing distance from the main surface of the base substrate in a thickness direction of the insulating film. The contact hole has a width which increases as the film density decreases.

According to another aspect of the present invention, there is provided a method of fabricating a semiconductor device. The method includes: depositing an insulating film over a main surface of a base substrate and a lower electrode formed on the main surface, by changing a process condition gradually or step-by-step for depositing the insulating film so as to decrease a film density with increasing time; and selectively etching the insulating film thereby to form a contact hole in the insulating film, the contact hole beings defined by a wall extending upwardly from a top surface of the lower electrode.

According to the present invention, the insulating film has the film density distribution in which the film density decreases with increasing distance from the main surface of the base substrate in the thickness direction of the insulating film. This enables the width of the contact hole to increase with increasing distance from the main surface of the base substrates in the thickness direction. Therefore, accurate control of the shape of the contact hole can be achieved with low fabrication cost.

### BRIEF DESCRIPTION OF THE DRAWINGS

In the attached drawings:

FIGS. 1A and 1B are cross-sectional views illustrating conventional passivation films;

FIGS. 2A and 2B are cross-sectional views, each illustrating step coverage of a barrier-metal film over the contact hole of the conventional passivation film;

FIG. 3 is a schematic cross-sectional view of a semiconductor device of an embodiment;

FIG. 4 illustrates an exemplary plasma CVD system used for deposition of a passivation film of the embodiment;

FIG. 5 is a schematic cross-sectional view of a semiconductor structure fabricated by a first processing step according to the embodiment;

FIG. 6 is a schematic cross-sectional view of a semiconductor structure fabricated by a second processing step according to the embodiment;

FIG. 7 is a schematic cross-sectional view of a semiconductor structure fabricated by a third processing step according to the embodiment;

FIG. 8 is a schematic cross-sectional view of a semiconductor structure fabricated by a fourth processing step according to the embodiment;

FIG. 9 is a schematic cross-sectional view of a semiconductor structure fabricated by a fifth processing step according to the embodiment;

FIG. 10 is a schematic cross-sectional view of a semiconductor structure fabricated by a sixth processing step according to the embodiment; and

FIG. 11 is a graphical representation illustrating a relationship between a low-frequency power and a film density of a passivation film.

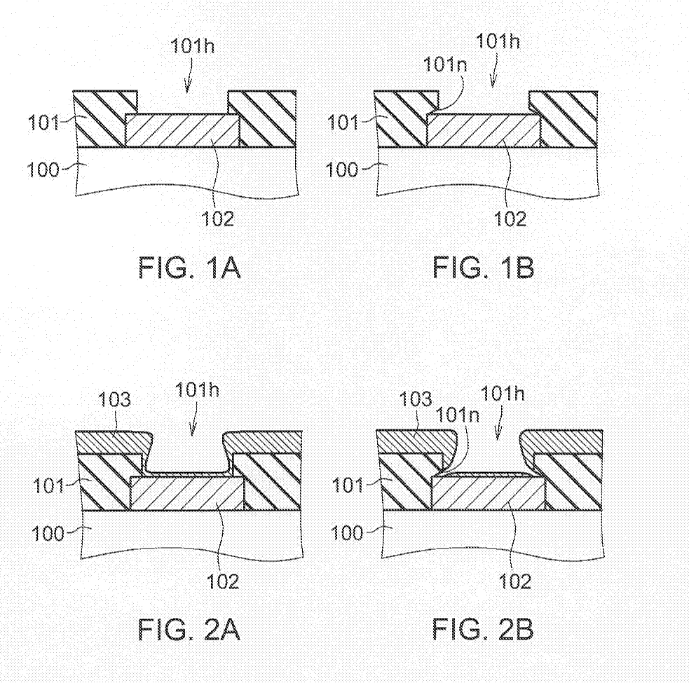

### DETAILED DESCRIPTION OF THE INVENTION

Embodiments of the invention will now be described with reference to the attached drawings, in which like elements are indicated by like reference characters.

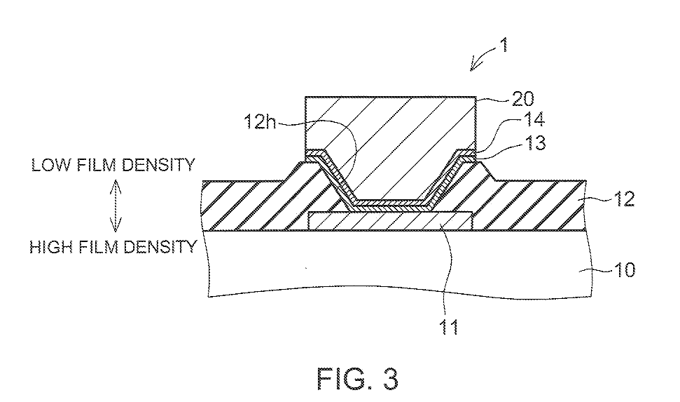

FIG. 3 is a schematic cross-sectional view of a semiconductor device 1 or an embodiment. The semiconductor device 1 includes a semiconductor substrate 10, a passivation film 12, a lower electrode (i.e., an electrode pad) 11, UBM layers (under-bump metal layers or underlying metal layers) 13, 14 and a bump electrode (i.e., an upper electrode) 20. The semiconductor substrate 10 is used as a base substrate on which a layered structure is formed. The lower electrode 11 is formed on the main surface of the semiconductor substrate 10, and the passivation film 12 is formed over the main surface of the semiconductor substrate 10. The UBM layers 13, 14 are formed on both the lower electrode 11 and the hole wall 12h of the passivation film 12. The bump electrode 20 is formed on the UBM layer 14. On the main surface of the semiconductor substrate 10, semiconductor device elements (not shown) such as field-effect transistors, capacitors and/or interconnect layers are formed. For example, an SOI (Silicon-On-Insulator) or bulk substrate made of single-crystal or polycrystalline semiconductor material such as silicon, or compound semiconductor material pan be used as the semiconductor substrate 10.

The lower electrode 11 is electrically connected to the semiconductor device elements. The lower electrode 11 is made of, for example, a metal material such as aluminum, and is patterned to have a rectangular top surface that have sides of lengths ranging from several micrometers to several dozen micrometers.

The passivation film 12 protects semiconductor device elements and interconnect layers of lower layers from mechanical damage and external contaminants such as wafer and moisture. The passivation film 12 can be formed by first depositing a nitride insulating film (e.g., a silicon nitride film, a silicon oxide film and/or a silicon oxynitride film) by a plasma CVD system such as an inductively coupled plasma CVD system or a CCP (capacitively-coupled plasma) CVD system, and then forming a contact hole defined by a hole wall 12h by photolithography and anisotropic etching of the nitride insulating film. In the deposition process using the plasma CVD system, at least one of controlling parameters defining a deposition condition is varied gradually or step-by-step such that the radical density of activated species varies gradually or step-by-step with increasing process time in the reactive chamber of the plasma CVD system. This enables the film density of the nitride insulating film to decrease gradually or step-by-step with increasing process time during deposition. Examples of the controlling parameters are an AC electric power supplied into the reactive chamber, a flow rate of source gases, a substrate temperature, and a pressure inside the reactive chamber.

As illustrated in FIG. 3, the passivation film 12 has a hole wall 12h that extends upwardly from the top surface of the lower electrode 11. The hole wall 12h has a tapered shape. The passivation film 12 has the film density distribution in which the film density decreases with increasing distance from the main surface of the semiconductor substrate 10 in the thickness direction of the passivation film 12, where the thickness direction is perpendicular to the main surface of the semiconductor substrate 10. The width of the hole wall 12h (i.e., the width of the contact hole) increases with decreasing film density, that is, with increasing distance from the main surface of the semiconductor substrate 10 in the thickness direction, thereby to form the tapered shape. This tapered shape may include a stepped shape.

The underlying metal layers 13, 14 are continuously formed on both the hole wall 12h and the top surface of the lower electrode 11. These underlying metal layers 13, 14 can in turn be formed by sputtering. The underlying metal layer 13 is formed to prevent constituent material of the bump electrode 20 from diffusing into the lower electrode 11 and forming intermetallic compounds, and to improve adhesion between the bump electrode 20 and the lower electrode 11. The underlying metal layer 13 is comprised of a single layer or multiple layers made of, for example, at least one of high melting point refractory metals such as titanium (Ti), tungsten (W) and nickel (Ni). The underlying metal layer 13 can be made of alloy composed of two or more elements selected from the high melting point refractory metals. The underlying metal layer 14 can be made of, for example, gold (Au).

Since the hole wall 12h has the tapered shape as described above, the underlying metal layers 13, 14 with uniform thicknesses can be easily formed. Thus, good step coverage of the underlying metal layers 13, 14 over the contact hole can be achieved.

The bump electrode 20 has a columnar shape and is formed above the lower electrode 11 via the underlying metal layers 13, 14. The bump electrode 20 can have a thickness ranging from several micrometers to several dozen micrometers. The bump electrode 20 can be made of, for example, metal material such as gold (Au), silver (Ag) and popper (Cu) and/or their alloy, and can by formed by electro-plating, electroless plating or physical vapor deposition.

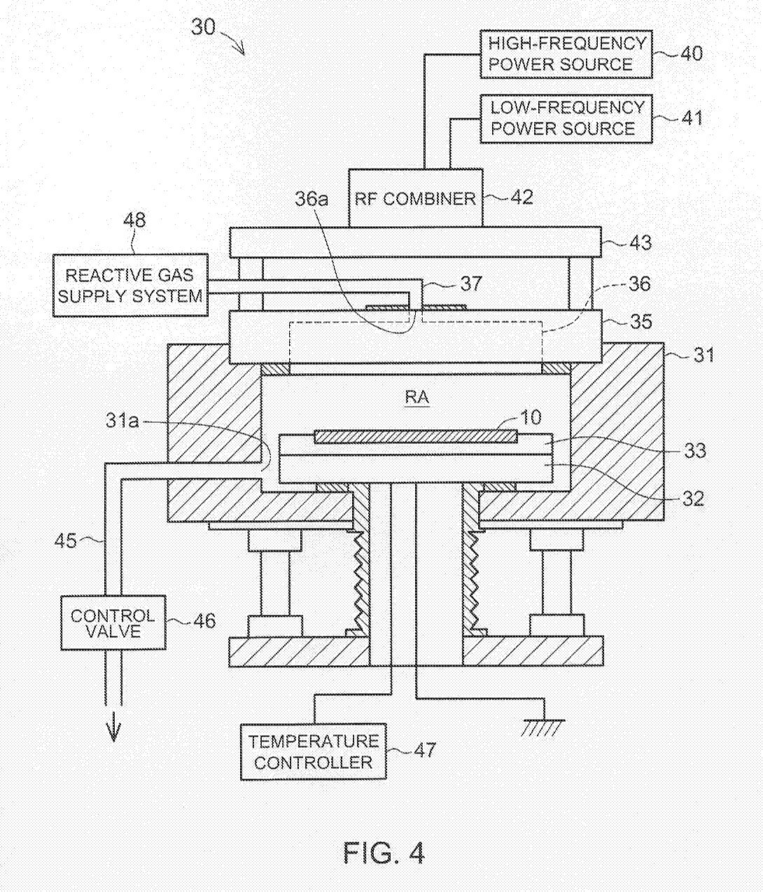

FIG. 4 schematically illustrates an exemplary CCP (Capacitively-Coupled Plasma)-CVD system 30 used for formation of the passivation film 12. In the present embodiment, in order to form the passivation film 12 having a film density distribution in which the film density varies a film density distribution in which the film density varies gradually or step-by-step in the thickness direction, the CCP-CVD system 30 is used, no limitation thereto intended. Alternatively, an inductively coupled plasma CVD system can be used to form the passivation film 12.

As illustrated in FIG. 4, the plasma CVD system 30 includes a reaction chamber 31, a susceptor 32 and a showerhead 35. The susceptor 32 supports the semiconductor substrate (i.e., a semiconductor water) 10 placed in the reaction chamber 31. The showerhead 35 is placed opposite to the susceptor 32. The reaction chamber 31 has an exhaust port (i.e., a reactor outlet) 31a that is connected to a vacuum pump (not shown) through an exhaust tube 45 and a control valve 46. Pressure in the reaction chamber 31 can be adjusted by controlling the opening of the control valve 46.

The showerhead 35 has a shower plate 36 that receives reactive gases from a reactant gas inlet 36a through a gas feed tube 37 and introduces the reactive gases into the reaction chamber 31. The shower plate 36 has a large number of fine holes for providing an even flow of the reactive gases into the reaction chamber 31. A reactive gas supply system 48 supplies the reactive gases to the shower plate 36 through the gas feed tube 37. The reactive gases are a mixture of source gases and chemically stable carrier gases. The reactive gas supply system 48 has a function of individually controlling the flow rates of the source gases and the chemically stable carrier gases.

The showerhead 35 also functions as a top electrode to which an AC electric power for plasma generation is applied by an RF combiner 42. The RF combiner 42 combines a high-frequency electric power (e.g., an electric power of frequency 13.56 MHz) supplied by a high-frequency power supply 40 and a low-frequency electric power (e.g., an electric power of frequency 430 kHz) supplied by a low-frequency power supply 41, thereby to generate the AC electric power to be supplied to the showerhead 35 (i.e., the top electrode) through the power transferring unit 43. The amplitudes of the low-frequency electric power and the high-frequency electric power are individually controlled by a controller (not shown).

On the other hand, the susceptor 32 functions as a bottom electrode, and is placed opposite to the showerhead 35 that functions as the top electrode. The susceptor 32 is connected to ground. On the susceptor 32, a top plate 33 is disposed to hold the semiconductor substrate 10. The susceptor 32 includes a heater (not shown) for heating the semiconductor substrate 10. A temperature controller 47 controls the operation temperature of the heater thereby to adjust the temperature (i.e., a substrate temperature) of the semiconductor substrate 10 in a prescribed range (for example, from 300 to 420 degrees centigrade).

Next, a method of fabricating the semiconductor device 1 will be described with reference to FIGS. 5 to 10. FIGS. 5 to 10 are schematic cross-sectional views of semiconductor structures fabricated by preferred process steps.

As illustrated in FIG. 5, a silicon nitride film 12C is deposited to cover the whole area of the main surface of the semiconductor substrate 10 by using the plasma CVD system 30 described above. In this deposition process, the semiconductor substrate 10 is placed on the susceptor 32 in the reaction chamber 31 of the plasma CVD system 30. The control value 46 then adjusts the pressure in the reaction chamber 31 to a prescribed value, and the temperature controller 47 controls the heater (not shown) of the susceptor 32 thereby to heat the semiconductor substrate 10 to a prescribed temperature. After the substrate temperature becomes stable, the reactive gas supply system 48 introduces reactive gases into a plasma generation area RA in the reaction chamber 31 through the showerhead 35 The reactive gases are mainly composed of silane (SiH₄), ammonia (NH₃) and N₂.

After the introduction of the reactive gases, the RF combiner 42 combines the high-frequency electric power and the low-frequency electric power to generate an AC electric power, and supplies the AC electric power to the showerhead 35 (i.e., the top electrode). As a result, plasma is generated in the plasma generation area RA. The plasma decomposes the source gases (silane and ammonia) into activated species or activated chemical species. Some of the activated species reach the top surface of the semiconductor substrate 10, and are adsorbed on the semiconductor substrate 10 to form the silicon nitride film 12C.

In order to obtain the desired thickness (e.g., several thousand angstroms) of the silicon nitride film 12C, the deposition time can be set in a range from about 60 to 90 seconds. During the deposition time, the AC electric power (unit: watts) is controlled to decrease gradually or step-by-step, and the spacial density of the activated species in the plasma generation area RA is varied with increasing process time. As a result, the silicon nitride film 12C is deposited. The silicon nitride film 12C has a film density distribution in which the film density decreases gradually or step-by-step with increasing distance from the main surface of the semiconductor substrate 10. In the deposition process, the higher the Si—N bonding density, the higher the film density becomes. On the other hand, the smaller the Si—N bonding density (i.e., the higher the Si—H and/or N—H bonding density), the smaller the film density becomes.

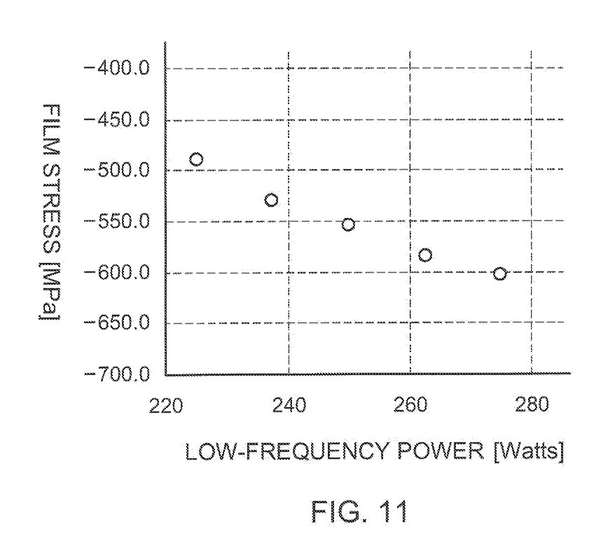

The silicon nitride film 12C has a compressive stress as a film stress. The larger the absolute value of the compressive stress, the higher the film density becomes. FIG. 11 is a graphical representation illustrating measurement results of the film stress (unit: MPa) of a silicon nitride film when the low-frequency electric power (unit: watts) varies. The deposition condition for obtaining the measurement results is: the high-frequency electric power is 550 watts; the frequency of the high-frequency electric power is 13.56 MHz; the frequency of the low-frequency electric power is 430 kHz; the flow rate of a silane (SiH₄) gas is 240 sccm; the flow rate of an ammonia (NH₃) gas is 1300 sccm; the flow rate of a nitrogen (N₂) gas is 600 sccm; a substrate temperature is 400 degrees centigrade; and a pressure inside the reactive chamber is 345.7 Pa.

As illustrated in FIG. 11, the higher the low-frequency electric power, the larger the absolute value of the compressive stress of the silicon nitride film becomes. Thus, it is understood that the film density of the silicon nitride film increases as the low-frequency electric power becomes high. In order to avoid problems such as stress migration with respect to a topmost interconnect metal layer of a semiconductor device, the lower limit of the compressive stress of the silicon nitride film is preferably minus 650 MPa. As seen in FIG. 11, the low-frequency electric power corresponding to the compressive stress of minus 650 MPa can be estimated to be about 300 Watts. Thus, it is preferable that the low-frequency electric power decreases gradually or step-by-step from about 300 Watts to about 250 Watts when the silicon nitride film 12C is deposited by the plasma CVD system 30. Further, in order to improve stability of the low-frequency electric power and control of the shape of the hole wall 12h, it is preferable that the low-frequency electric power be varied in steps of about 5 watts corresponding to about 10 MPa.

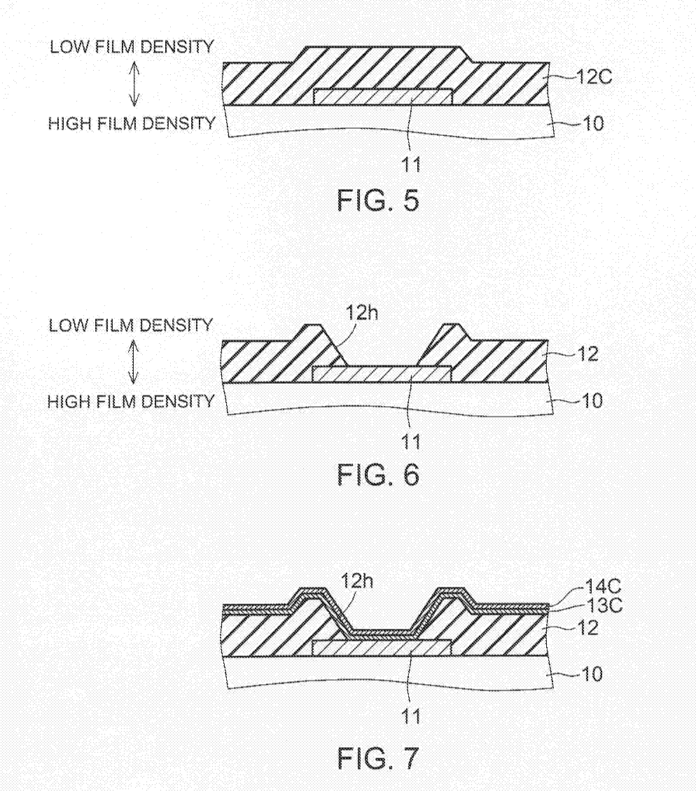

After the deposition of the silicon nitride film 12C (FIG. 5), the silicon nitride film 12C is patterned by photolithography and anisotropic etching. As a result, a passivation film 12 having a hole wall 12h as shown in FIG. 6 is formed. In the anisotropic etching process, the etch-rate of the silicon nitride layer 12C depends upon the film density, and the etching of a low-density film progresses more rapidly than the etching of a high-density film. Therefore, as illustrated in FIG. 6, the width of the hole wall 12h increases with increasing distance from the main surface of the semiconductor substrate 10. Thus, the hole wall 12h has a tapered shape.

After the formation of the passivation film 12, an underlying metal layer 13C such as a TiW alloy layer is deposited on the whole area including both the exposed surface of the lower electrode 11 and the hole wall 12h by a sputtering process. The underlying metal layer 14C such as an Au layer is then deposited on the underlying metal layer 13C by a sputtering process as illustrated in FIG. 7.

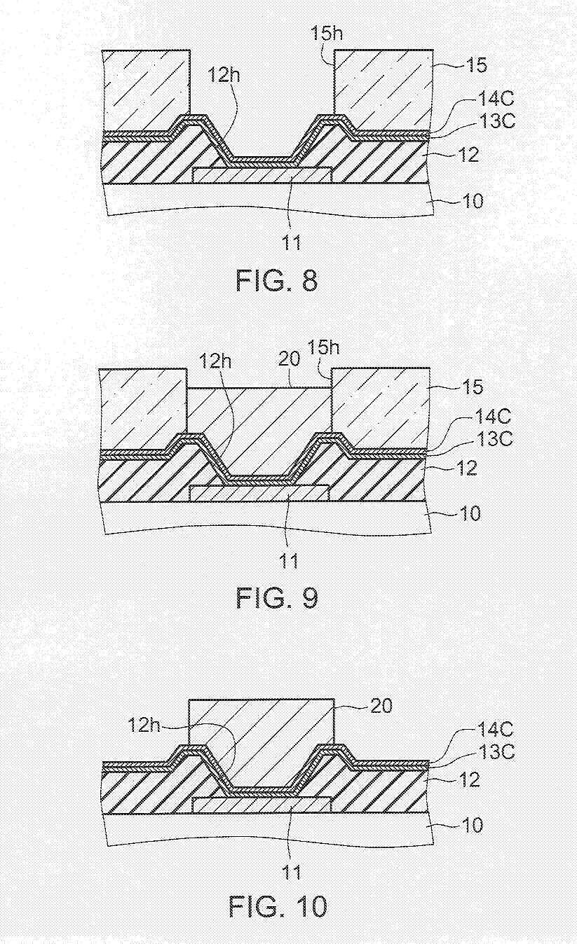

Next, a resist layer 15 is formed by first coating photosensitive resin on the structure of FIG. 7, and then patterning the coated photosensitive resin by photolithography. As illustrated in FIG. 8, the resist layer 15 has an opening portion 15h.

Next, the semiconductor substrate 10 is electroplated using the underlying metal layer 14C as a seed layer in a plating solution of, for example, potassium cyanide or sodium gold sulfite. As a result, the bump electrode 20 as illustrated in FIG. 9 is formed in the opening portion 15h.

The resist layer 15 is removed by an ashing process as illustrated in FIG. 10.

Next, the underlying metal layer 14C is selectively etched using the bump electrode 20 as an etching mask by wet etching using an etch solution such as an iodine and/or potassium iodide solution. The underlying metal layer 13C is then selectively etched using the hump electrode 20 as an etching mask by wet etching using as etch solution such as a hydrogen peroxide solution. As a result, the semiconductor device 1 as illustrated in FIG. 3 is fabricated.

As described above, the passivation film 12 of the embodiment has the film density distribution in which the film density decreases gradually or step-by-step with increasing distance from the main surface of the semiconductor substrate 10 in the thickness direction. When the hole wall 12h is formed by selectively etching the passivation film 12C, the etch-rate varies depending upon the film density. This etching process forms the tapered wall 12h of the contact hole, and enables accurate control of the tapered shape of the hole wall 12h.

According he the method of fabricating the semiconductor device 1, the film density distribution of the passivation film 12 is obtained by varying the deposition condition in the plasma CVD process. Thus, the tapered shape of the hole wall 12h can be formed without an additional process step and with low fabrication cost compared with the prior art.

The preceding embodiment of the invention and the illustrative drawings are exemplary but not limiting. For example, contact holes or through-holes for electrical connections of lower interconnect layers to upper interconnect layers are also etched in interlayer dielectric films of semiconductor devices. The above described deposition process and etching process can be applied to the interlayer dielectric film. This enables formation of the interlayer dielectric film having a film density distribution in which a film density varies gradually or step-by-step in its thickness direction, and formation of a tapered shape of the contact hole or through-hole.

In the above-described embodiment, the bump electrode 20 is formed on the underlying metal layers 13, 14 formed over the hole wall 12h. Alternatively, in a wafer level CSP (Chip Scale Packaging) process, a redistribution layer can be formed on an underlying metal layer formed over the hole wall 12h. The wafer level CSP is a packaging technology where a packaging process is carried out at the wafer level before dicing.

Those skilled in the art will recognize that further variations are possible within the scope of the invention, which is defined in the appended claims.

What is claimed is:

1. A semiconductor device comprising:
a base substrate;
a lower electrode formed on a main surface of the base substrate; and
an insulating film formed over the lower electrode and the main surface of the base substrate and having a contact hole defined by a wall extending upwardly from a top surface of the lower electrode, the insulating film having a film density distribution in which a film density decreases with increasing distance from the main surface of the base substrate in a thickness direction of the insulating film, the contact hole having a width which increases as the film density decreases.

2. The semiconductor device as set forth in claim 1, further comprising:
an underlying metal layer continuously formed on both the top surface of the lower electrode and the wall of the insulating film; and
an upper electrode formed on the underlying metal layer.

3. The semiconductor device as set forth in claim 1, wherein the insulating film includes a nitride film.

4. The semiconductor device as set forth in claim 2, wherein the upper electrode is formed by a plating process using the underlying metal layer as a seed layer.

5. The semiconductor device as set forth in claim 1, wherein the base substrate includes a semiconductor substrate on which a semiconductor device element is formed.

6. A method of fabricating a semiconductor device, comprising:
depositing an insulating film over a main surface of a base substrate and a lower electrode formed on the main surface, by changing a process condition gradually or step-by-step for depositing the insulating film so as to decrease a film density with increasing time; and
selectively etching the insulating film thereby to form a contact hole in the insulating film, the contact hole being defined by a wall extending upwardly from a top surface of the lower electrode.

7. The method of fabricating a semiconductor device as set forth in claim 6, further comprising:
forming an underlying metal layer as a continuous layer on both an exposed portion of the top surface and one wall; and
forming an upper electrode on the underlying metal layer.

8. The method of fabricating a semiconductor device as set forth in claim 6, wherein said depositing an insulating film is performed by using a plasma chemical vapor deposition system.

9. The method of fabricating a semiconductor device as set forth in claim 8, wherein the plasma chemical vapor deposition system includes:
a pair of opposed electrodes being spaced apart from each other;
a gas supply system for supplying source gases for forming the insulting film; and
an AC power source for supplying an electric power to at least one of the opposed electrodes thereby to generate plasma decomposing the source gases into activated species, the AC power source supplying the electric power that decreases with said increasing time thereby to change the process condition gradually or step-by-step.

10. The method of fabricating a semiconductor device as set forth in claim 9, wherein the AC power source includes:
a low-frequency power source for supplying a first electric power in a low-frequency range, the first electric power decreasing with said increasing time thereby to change the process condition gradually or step-by-step;
a high-frequency power source for supplying a second electric power in a high-frequency range higher than the low-frequency range; and
a power combiner for combining the first and second electric powers thereby to generate the electric power.

11. The method of fabricating a semiconductor device as set forth in claim 9, wherein the gas supply system supplies the source gases for forming a nitride film as the insulating film.

12. The method of fabricating a semiconductor device as set forth in claim 7, wherein said forming an underlying metal layer is performed by a sputtering process.
